(19) United States
(12) Patent Application Publication
(10) Pub. No.: US 2020/0355441 A1
(43) Pub. Date: Nov. 12, 2020

(54) INTEGRATED VAPOR CHAMBER AND MANUFACTURING METHOD THEREOF

(71) Applicant: TAIWAN MICROLOOPS CORP., New Taipei City (TW)

(72) Inventor: Chun-Hung LIN, New Taipei City (TW)

(21) Appl. No.: 16/406,684

(22) Filed: May 8, 2019

(51) Int. Cl. F28D 15/02; G06F 1/20; F28D 15/04; H05K 7/20; B23P 15/26

(52) U.S. Cl. CPC F28D 15/0233; G06F 1/20; F28D 15/046; B23P 2700/09; F28D 15/0283; B23P 15/26; H05K 7/20336

(57) ABSTRACT

Disclosed are an integrated vapor chamber and its manufacturing method, the vapor chamber includes a casing base, a fin, a sealed portion and a working fluid, and the casing base is formed by an evacuation method and includes a bottom plate, a top plate, a side plate, and a cavity formed and enclosed by the bottom plate, the top plate and the side plate. Each fin is formed and extended from a surface of the top plate with its back facing the bottom plate, and each sealed portion is formed at the front and rear ends of the cavity separately, and the working fluid is filled into the cavity. The vapor chamber not just features easy manufacturing only, but also provides good heat dissipation effect.

### BACKGROUND OF THE INVENTION

### 1. Technical Field

The technical field relates to a cooling technology, and more particularly to an integrated vapor chamber and its manufacturing method.

### 2. Description of Related Art

As the computing speed of electronic components becomes increasingly higher, the amount of heat generated by these electronic components is also increasing. To overcome the issue of high heat generation effectively, related manufacturers use vapor chambers with good thermal conductivity extensively, but the conventional vapor chambers still require improvements on their low thermal conduction performance, high manufacturing cost, and difficult manufacturing process, etc.

In general, the conventional vapor chamber includes an upper casing, a lower casing, and a capillary tissue installed in an internal space between the upper and lower casings, and then the upper and lower casing are engaged with each other by soldering, and a working fluid is filled into the space between the upper and lower casings, and finally manufacturing processes including an air-removing and pipe-sealing process are performed to complete the manufacture of the vapor chamber.

Although the conventional vapor chamber has a satisfactory thermal conduction performance, its actual use has the following problems. Since the sealing length between the upper and lower casings also covers the length of each side of the upper and lower casings, so that the soldering and sealing processes becomes quite cumbersome and difficult. In the soldering and sealing process of the upper and lower casings, the capillary tissue inside the vapor chamber is reheated since the manufacturing temperature is too high, and thus poor conditions such as the upper and lower casings being peeled off or separated from each other may occur easily. A change between temperature and pressure occurs constantly during the using process taken place in the cavity of the vapor chamber, which may cause leakage at the sealed or soldered joint of the upper and lower casings.

In view of the aforementioned drawbacks of the conventional vapor chamber, the discloser of this disclosure based on years of experience in the related industry to conduct extensive research and experiment, and finally provided a feasible solution to overcome the drawbacks of the prior art.

### SUMMARY OF THE INVENTION

Therefore, it is a primary object of this disclosure to overcome the drawbacks of the prior art by providing an integrated vapor chamber and its manufacturing method, and the integrated vapor chamber not just has an easy-to-manufacture feature only, but also provides a good heat dissipation effect.

To achieve the aforementioned and other objectives, this disclosure provides an integrated vapor chamber comprising a casing base, a plurality of fins, two sealed portions and a working fluid, characterized in that the casing base is formed by an evacuation method; the casing base comprises a bottom plate, a top plate formed above the bottom plate, a side plate coupled to both sides of the bottom plate and the top plate separately, and a cavity formed and enclosed by the bottom plate, the top plate and each of the side plates; each fin is formed and extended from a surface of the top plate with its back facing the bottom plate; each sealed portion is formed at the front and rear ends of the cavity separately; and the working fluid is filled into the cavity.

To achieve the aforementioned and other objectives, this disclosure provides an integrated vapor chamber manufacturing method comprising the following steps:

(a) Form a casing base material and a plurality of fin materials coupled to the casing base material by an evacuation method, and form a cavity in the casing base material.

(b) Perform a sectional cutting process of the casing base material and each fin material, and form an opening at the front and rear ends of the cavity separately.

(c) Perform a pressure-sealing process of each opening to form a sealed portion after the sectional cutting process.

(d) Fill a working fluid into the cavity, and carry out an air-removing and pipe-sealing process.

To achieve the aforementioned and other objectives, this disclosure further provides another integrated vapor chamber manufacturing method comprising the following steps:

(a1) Form a casing base material by an evacuation method, and form a cavity in the casing base material.

(b1) Perform a sectional cutting process of the casing base material, and form an opening at the front and rear ends of the cavity separately.

(c1) Form a plurality of fins on a surface of the casing base material by a skiving method.

(d1) Perform a pressure-sealing process of each opening to form a sealed portion after the sectional cutting process.

(e1) Fill a working fluid into the cavity, and carry out an air-removing and pipe-sealing process.

This disclosure has the following effects. The leakage occurred during the process of using the vapor chamber can be controlled effectively by reducing the sealed and soldered length, and the poor conditions including the easy peel-off or detachment of the conventional capillary can be overcome by the integrated structure of the capillary structure and the casing base, and the thermal conduction and dissipation performance between the casing base and each fin can be improved by the integrated structure of each fin and the casing base.

### BRIEF DESCRIPTION OF THE DRAWINGS

FIG. 1 is a perspective view of a casing base and each fin of this disclosure;

FIG. 2 is a cross-sectional view of a casing base and each fin of this disclosure;

FIG. 3 is a perspective view of an integrated vapor chamber of this disclosure;

FIG. 4 is a cross-sectional view of an integrated vapor chamber of this disclosure;

FIG. 5 is a cross-sectional view of an integrated vapor chamber of another embodiment of this disclosure;

FIG. 6 is a flow chart of an integrated vapor chamber manufacturing method of this disclosure; and

FIG. 7 is a flow chart of another integrated vapor chamber manufacturing method of this disclosure.

### DESCRIPTION OF THE PREFERRED EMBODIMENTS

The technical contents of this disclosure will become apparent with the detailed description of preferred embodiments accompanied with the illustration of related drawings as follows. It is intended that the embodiments and drawings disclosed herein are to be considered illustrative rather than restrictive.

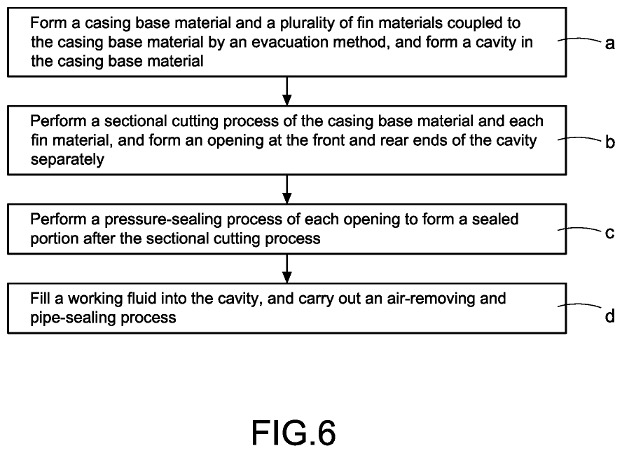

With reference to FIG. 6 for an integrated vapor chamber manufacturing method in accordance with this disclosure, the method comprises the following steps:

(a) Form a casing base material and a plurality of fin materials coupled to the casing base material by an evacuation method, and form a cavity A in the casing base material.

(b) Perform a sectional cutting process of the casing base material and each fin material, and form an opening at the front and rear ends of the cavity A separately.

(c) Perform a pressure-sealing process of each opening to form a sealed portion after the sectional cutting process.

(d) Fill a working fluid into the cavity A, and carry out an air-removing and pipe-sealing process.

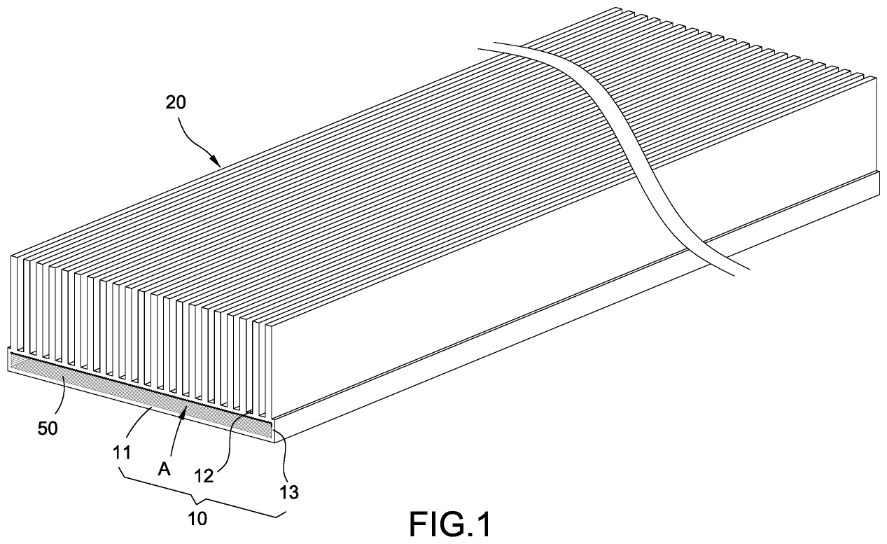

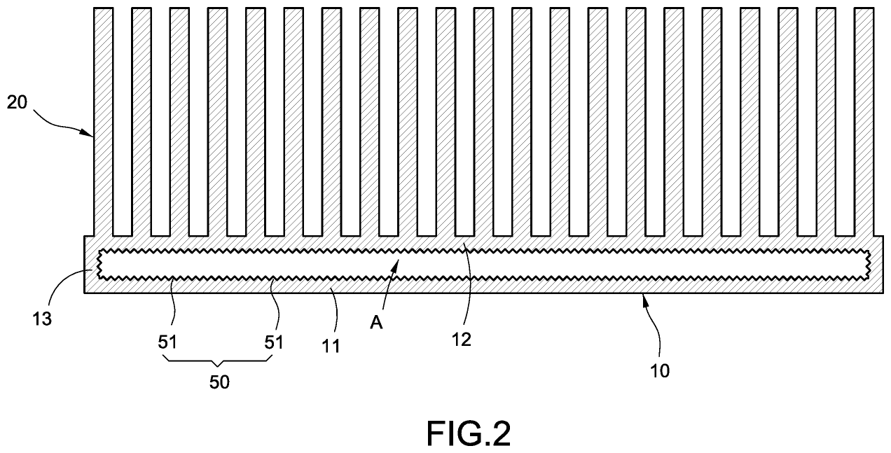

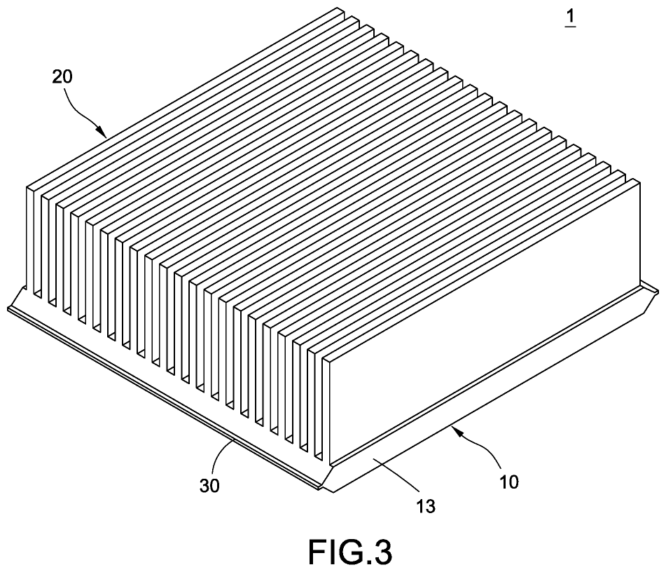

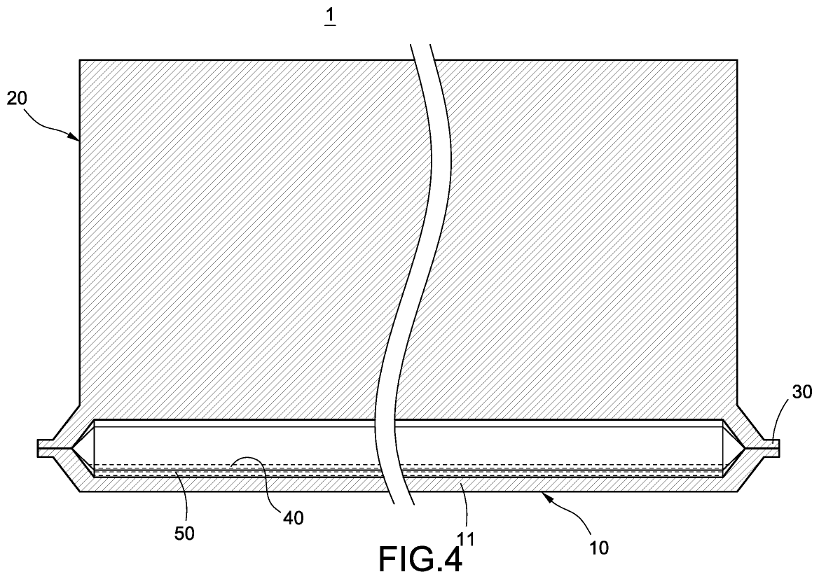

With reference to FIGS. 1 to 4 for an integrated vapor chamber of this disclosure, the integrated vapor chamber 1 comprises a casing base 10, a plurality of fins 20, two sealed portions 30, and a working fluid 40.

The casing base 10 is made of a material with good thermal conductivity such as aluminum, copper, or their alloys, and formed by a drawing extension method. The casing base 10 comprises a bottom plate 11 and a top plate 12, wherein the bottom plate 11 is a long strip plate, and the top plate 12 is parallel to the bottom plate 11 and disposed at the top of the bottom plate 11, and both sides of the bottom plate 11 and both sides of the top plate 12 are coupled with a side plate 13, and a cavity A is enclosed and formed by the bottom plate 11, the top plate 12, and each side plate 13.

Each fin 20 is formed and extended from a surface of the top plate 12 with its back facing the bottom plate 11. In this embodiment, each fin 20 is formed with the casing base 10 by the aforementioned drawing extension process. Besides the aforementioned manufacturing method, each fin 20 may also be formed by a cutting tool in a skiving process before the drawing extension process is completed.

After the drawing extension process of the casing base material and each fin material is completed, a cutting tool is used to cut the casing base material and each fin material into sections, so that an opening is formed at both front and rear ends of the casing base 10 separately after the sectional division process, and the end of each fin 20 above the opening can be removed and manufactured after the sectional division process to facilitate the subsequent press-processing.

A pressing tool (not shown in the figure) is used to form a sealed portion 30 of each opening by a pressure-sealing process, wherein an air-removing tube (not shown in the figure) is reserved during the pressure-sealing process, and then the working fluid 40 is filled into the cavity A through the air-removing tube.

Finally, the semi-finished product of the vapor chamber is performed with an air-removing process by a heating method and a pipe-sealing process by a soldering method to obtain the integrated vapor chamber 1 of this disclosure.

The integrated vapor chamber 1 of this disclosure further comprises a capillary structure 50 which is formed by a plurality of grooves 51, and each groove 51 is formed with the casing base 10 by the aforementioned drawing extension method, and each groove 5 is formed on the inner walls of the bottom plate 11, the top plate 12 and each of the side plates 13. Similarly, the capillary structure may be a metal braided mesh, and the metal braided mesh is disposed on the inner walls of the bottom plate 11, the top plate 12, and each of the side plates 13.

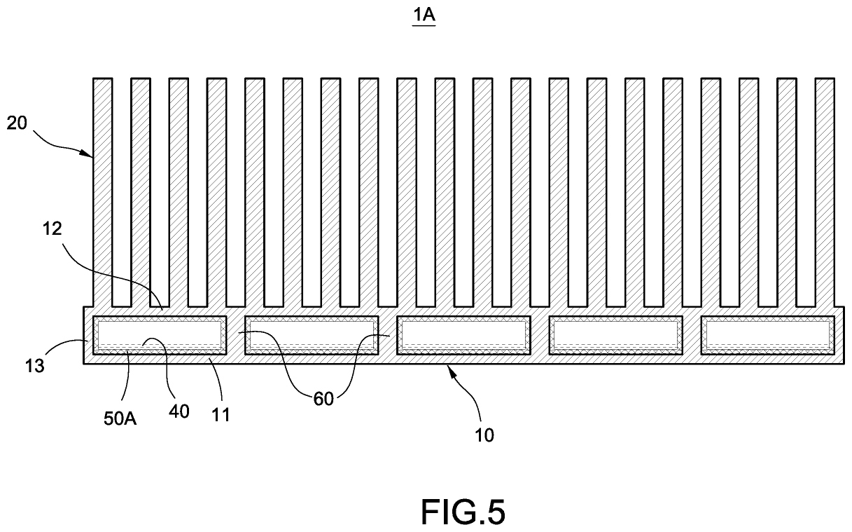

In another embodiment of the integrated vapor chamber of this disclosure as shown in FIG. 5, the integrated vapor chamber 1A further comprises a plurality of support columns 60, and each support column 60 is formed with the casing base 10 by the drawing extension method, wherein the support columns 60 are coupled between the bottom plate 11 and the top plate 12 and formed in the cavity A. In this embodiment, the capillary structure 50A is a metal braided mesh disposed on the inner walls of the bottom plate 11, the top plate 12 and each of the side plates 13 and a surface of each support column 60.

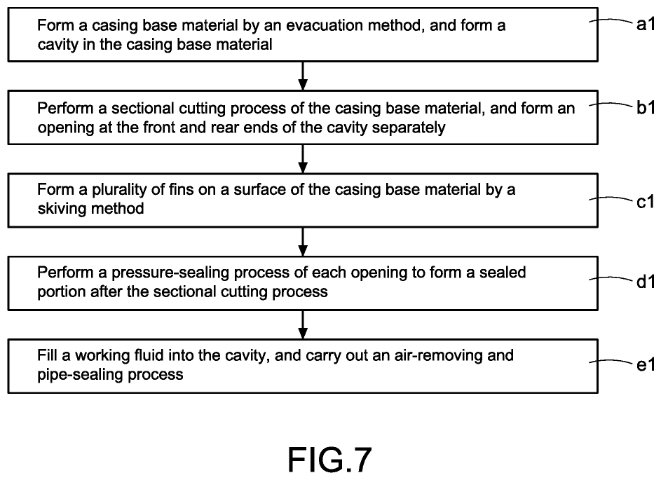

With reference to FIG. 7 for another integrated vapor chamber manufacturing method of this disclosure, the method comprises the following steps:

(a1) Form a casing base material by an evacuation method, and form a cavity A in the casing base material.

(b1) Perform a sectional cutting process of the casing base material, and form an opening at the front and rear ends of the cavity A separately.

(c1) Form a plurality of fins 20 on a surface of the casing base material by a skiving method.

(d1) Perform a pressure-sealing process of each opening to form a sealed portion 30 after the sectional cutting process.

(e1) Fill a working fluid into the cavity A, and carry out an air-removing and pipe-sealing process.

Wherein, the step (c1) is carried out before the step (b1).

In summation of the description above, this disclosure can surely achieve the expected effects and overcome the drawbacks of the prior art, and this disclosure also complies with patent application requirements, and thus is duly filed for patent application.

While this disclosure has been described by means of specific embodiments, numerous modifications and variations could be made thereto by those skilled in the art without departing from the scope and spirit of this disclosure set forth in the claims.

What is claimed is:

1. An integrated vapor chamber, comprising:
a casing base, formed by an evacuation method, and further comprising a bottom plate, a top plate formed above the top of the bottom plate, a side plate coupled to both sides of the bottom plate and the top plate separately, and a cavity formed and enclosed by the bottom plate, the top plate and each side plate;
a plurality of fins, formed and extending from a surface of the top plate with its back facing the bottom plate;
two sealed portions, formed at the front and rear ends of the cavity respectively; and
a working fluid, filled into the cavity.

2. The integrated vapor chamber according to claim 1, further comprising a capillary structure which is formed by a plurality of grooves, each being formed with the casing base by the evacuation method, and formed directly on the inner walls of the bottom plate, the top plate and each side plate.

3. The integrated vapor chamber according to claim 1, further comprising a plurality of support columns, each being formed with the casing base by the evacuation method, and each support column being coupled between the bottom plate and the top plate and formed in the cavity.

4. The integrated vapor chamber according to claim 3, further comprising a capillary structure which is a metal braided mesh disposed on the inner walls of the bottom plate, the top plate and each side plate, and a surface of each support column.

5. The integrated vapor chamber according to claim 1, further comprising a capillary structure which is a metal braided mesh disposed on the inner walls of the bottom plate, the top plate and the inner wall of each side plate.

6. The integrated vapor chamber according to claim 1, wherein each fin is formed with the casing base by the evacuation method.

7. The integrated vapor chamber according to claim 1, wherein each fin is formed by a skiving method.

8. An integrated vapor chamber manufacturing method, comprising the steps of:
(a) forming a casing base material and a plurality of fin materials coupled to the casing base material by an evacuation method, and forming a cavity in the casing base material;
(b) performing a sectional cutting process of the casing base material and each fin material, and forming an opening at the front and rear ends of the cavity separately;
(c) performing a pressure-sealing process of each opening to form a sealed portion after the sectional cutting process; and
(d) filling a working fluid into the cavity, and carrying out an air-removing and pipe-sealing process.

9. The integrated vapor chamber manufacturing method according to claim 8, further comprising a capillary structure which is formed by a plurality of grooves, each being formed with the casing base material by the evacuation method.

10. The integrated vapor chamber manufacturing method according to claim 8, further comprising a plurality of support columns, each being formed with the casing base material by the evacuation method.

11. The integrated vapor chamber manufacturing method according to claim 10, further comprising a capillary structure which is a metal braided mesh disposed in the cavity.

12. The integrated vapor chamber manufacturing method according to claim 8, further comprising a capillary structure which is a metal braided mesh disposed in the cavity.

13. An integrated vapor chamber manufacturing method, comprising the steps of:
(a1) forming a casing base material by an evacuation method, and forming a cavity in the casing base material;
(b1) performing a sectional cutting process of the casing base material, and forming an opening at the front and rear ends of the cavity separately;
(c1) forming a plurality of fins on a surface of the casing base material by a skiving method;
(d1) performing a pressure-sealing process of each opening to form a sealed portion after the sectional cutting process; and
(e1) filling a working fluid into the cavity, and carrying out an air-removing and pipe-sealing process.

14. The integrated vapor chamber manufacturing method according to claim 13, wherein the step (c1) is carried out before the step (b1).

15. The integrated vapor chamber manufacturing method according to claim 13, further comprising a capillary structure which is formed by a plurality of grooves, and each groove being formed with the casing base material by the evacuation method.

16. The integrated vapor chamber manufacturing method according to claim 13, further comprising a plurality of support columns, each being formed with the casing base material by the evacuation method.

17. The integrated vapor chamber manufacturing method according to claim 16, further comprising a capillary structure which is a metal braided mesh disposed in the cavity.

18. The integrated vapor chamber manufacturing method according to claim 13, further comprising a capillary structure which is a metal braided mesh disposed in the cavity.
